(19) United States
(12) Patent Application Publication
(10) Pub. No.: US 2026/0129880 A1
(43) Pub. Date: May 7, 2026

(54) THREE-LAYER VERTICAL SHUNT RESISTOR, POWER SEMICONDUCTOR, AND METHOD FOR MANUFACTURING THE THREE-LAYER VERTICAL SHUNT RESISTOR

(71) Applicant: KOSTECSYS CO., LTD., Incheon (KR)

(72) Inventor: Tae Seong HAN, Incheon (KR)

(73) Assignee: KOSTECSYS CO., LTD., Incheon (KR)

(21) Appl. No.: 19/027,744

(22) Filed: Jan. 17, 2025

(30) Foreign Application Priority Data
Nov. 5, 2024 (KR) 10-2024-0155729

(51) Int. Cl. H10D 1/47; H10D 1/00

(52) U.S. Cl. CPC H10D 1/474; H10D 1/021

(57) ABSTRACT

A three-layer vertical shunt resistor, a power semiconductor and a method for manufacturing a three-layer vertical shunt resistor are disclosed. The three-layer vertical shunt resistor includes a first resistor body including a resistive material, a second resistor body coupled to an upper portion of the first resistor body and formed of a resistive material having better electrical conductivity than the resistive material of the first resistor body, a first terminal coupled to a lower portion of the first resistor body and formed of a metal material having better electrical conductivity than the resistive material of the first resister body, and a second terminal coupled to a lower portion of the first resistor body and arranged to be spaced apart from the first terminal and formed of a metal material having better electrical conductivity than the resistive material of the first resistor body.

### CROSS REFERENCE TO RELATED APPLICATION

This application claims the benefit of the Korean Application No. 10-2024-0155729, filed on Nov. 5, 2024, which is hereby incorporated by reference in its entirety.

### BACKGROUND OF THE INVENTION

### Field of the Invention

The present invention relates to a three-layer vertical shunt resistor, a power semiconductor, and a method for manufacturing the three-layer vertical shunt resistor, and more particularly, to a vertical shunt resistor having a three-layer structure, a power semiconductor, and a method for manufacturing the vertical shunt resistor.

### Discussion of the Related Art

Shunt resistors are low-value precision resistors used as current measuring elements in high-current circuits. Shunt resistors can be inserted into the monitored circuit and used as current sensors. Shunt resistors can be used as current sensors by measuring the voltage drop that occurs across the two terminals of the shunt resistor inserted into the monitored circuit and inferring the amount of current in the circuit through Ohm's law (I=V/R).

Shunt resistors, which are current sensors, are required to be highly precise and miniaturized for accurate current measurement in inverters, battery management systems and charging systems of xEV electric vehicles, solar inverters, etc., protection of electronic circuits from overvoltage, and equal charging/discharging of batteries. As next-generation power semiconductors such as SiC and GaN rapidly increase, the demand for shunt resistors is greatly increasing.

Recently, in the cooling method of power semiconductors for electric vehicles, the demand for double-sided cooling method, which has superior cooling performance and allows more compact power module size compared to conventional single-sided cooling type power modules, is greatly increasing, and shunt resistors are built into power modules. However, conventional shunt resistors have long electrode lengths, which makes it difficult to miniaturize and integrate power module packaging.

### SUMMARY OF THE INVENTION

Accordingly, the present invention is directed to a three-layer vertical shunt resistor, a power semiconductor and a method for manufacturing the three-layer vertical shunt resistor that substantially obviate one or more problems due to limitations and disadvantages of the related art.

The problem to be solved by the present invention lies on providing a three-layer vertical shunt resistor, a power semiconductor and a method for manufacturing the three-layer vertical shunt resistor without defects, non-uniformities or voids at the joint between the resistive material and the electrode material.

Another problem to be solved by the present invention lies on providing a three-layer vertical shunt resistor, a power semiconductor and a method for manufacturing a three-layer vertical shunt resistor that can be manufactured in an ultra-small size while providing high power capacity.

Another problem to be solved by the present invention lies on providing a three-layer vertical shunt resistor, a power semiconductor and a method for manufacturing a three-layer vertical shunt resistor, which can be manufactured so that the terminals of the shunt resistor are formed in the same layer and direction.

The three-layer vertical shunt resistor according to the present invention includes a first resistor body including a resistive material, a second resistor body coupled to an upper portion of the first resistor body and formed of a metal material having better electrical conductivity than the resistive material, a first terminal coupled to a lower portion of the first resistor body and formed of a metal material having better electrical conductivity than the resistive material, and a second terminal coupled to a lower portion of the first resistor body and arranged to be spaced apart from the first terminal and formed of a metal material having better electrical conductivity than the resistive material.

Preferably, the resistive material of the first resistor body includes at least one of a Cu—Mn alloy, a Cu—Ni alloy, a Ni—Cr alloy, a Cu—Mn—Ni alloy, and an Fe—Cr alloy.

Preferably, the metal material of the second resistor body may be formed of a single material.

Preferably, the metal material of the second resistor body may be one of Cu, Ni, and Cr.

Preferably, the thickness of the first resistor body may be 0.15 mm to 1.0 mm.

Preferably, the thickness of the second resistor body may be 0.02 mm to 0.7 mm.

Preferably, the thickness of the first terminal or the thickness of the second terminal may be 0.1 mm to 0.8 mm.

Preferably, the second resistor body and the first terminal body may be diffusion-bonded by a current applied to the upper and lower surfaces of the first resistor body.

The power semiconductor according to the present invention includes the three-layer vertical shunt resistor according to the present invention.

The method for manufacturing the three-layer vertical shunt resistor according to the present invention includes a step of preparing a first resistor body including a resistive material, a step of preparing a second resistor body formed of a resistive material having better electrical conductivity than the resistive material of the first resistor body, a step of preparing a first terminal and a second terminal formed of a metal material having better electrical conductivity than the resistive material of the first resistor body, a step of forming a laminate by laminating the first resistor body between the second resistor body and the first terminal, the first resistor body between the second resistor body and the second terminal, and the first terminal and the second terminal in a spaced apart form, and a step of applying a current to the laminate to diffusion-bond the first terminal, the second terminal, the first resistor body, and the second resistor body.

According to the three-layer vertical shunt resistor, power semiconductor and method for manufacturing the three-layer vertical shunt resistor of the present invention, by applying a current and joining the first terminal and the second terminal formed of the electrode material, the first resistor body formed of the resistive material, and the second resistor body formed of the resistive material in a diffusion bonding manner, a three-layer vertical shunt resistor without defects, unevenness, and voids at the joining portion may be provided.

In addition, according to the present invention, since the electrode material and the resistive material are arranged vertically, a shunt resistor having the same capacity can be manufactured in a shorter length, so that an ultra-small three-layer vertical shunt resistor can be provided while providing high power capacity.

In addition, according to the present invention, since a plurality of terminals can be formed under the first resistor body, a three-layer vertical shunt resistor having a plurality of electrodes in the same direction on the same layer can be provided.

### BRIEF DESCRIPTION OF DRAWINGS

The embodiments will be described in detail with reference to the following drawings in which like reference numerals refer to like elements wherein:

FIG. 1 is a drawing illustrating the overall shape of a three-layer vertical shunt resistor according to a preferred embodiment of the present invention.

FIG. 2 is a plan view of a three-layer vertical shunt resistor according to a preferred embodiment of the present invention.

FIG. 3 is a bottom view of a three-layer vertical shunt resistor according to a preferred embodiment of the present invention.

FIG. 4 is a cross-sectional view of a three-layer vertical shunt resistor according to a preferred embodiment of the present invention.

FIG. 5 is a drawing illustrating a shunt circuit of the three-layer vertical shunt resistor of FIG. 1.

FIG. 6 is a drawing for explaining the resistance value of a three-layer vertical shunt resistor according to a preferred embodiment of the present invention.

FIG. 7 is a drawing illustrating a semiconductor package according to a preferred embodiment of the present invention.

FIG. 8 is a flowchart illustrating the process of performing a preferred embodiment of a method for manufacturing a three-layer vertical shunt resistor according to the present invention.

FIG. 9 is a process diagram illustrating the process of performing a preferred embodiment of a method for manufacturing a three-layer vertical shunt resistor according to the present invention.

FIG. 10 is a diagram illustrating a diffusion bonding process.

FIG. 11 is a diagram illustrating a photograph of a bonding portion of a three-layer vertical shunt resistor according to a preferred embodiment of the present invention.

### DETAILED DESCRIPTION OF THE INVENTION

Reference will now be made in detail to the preferred embodiments of a three-layer vertical shunt resistor, a power semiconductor, and a method for manufacturing the three-layer vertical shunt resistor, examples of which are illustrated in the accompanying drawings. It is to be understood that both the foregoing general description and the following detailed description of the present invention are exemplary and explanatory and are intended to provide further explanation of the invention as claimed. Furthermore, it is to be understood that the technical spirit and the fundamental structure and operation of the present invention will not be limited to the description of the present invention.

In addition, although the terms used in the present invention are selected from generally known and used terms, some of the terms mentioned in the description of the present invention have been selected by the applicant at his or her discretion, the detailed meanings of which are described in relevant parts of the description herein. Furthermore, it is required that terms used in the present invention should be defined, not simply by the actual terms used but by the meaning of each term lying within and also based upon the overall content of the description of the present invention.

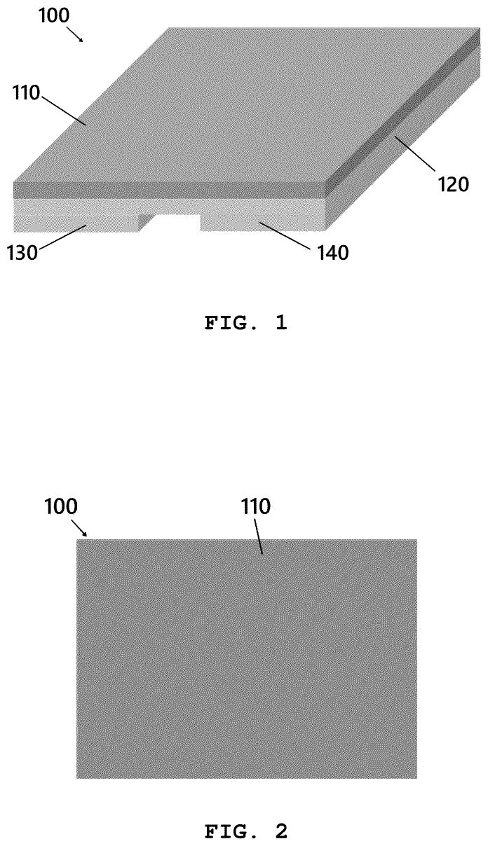

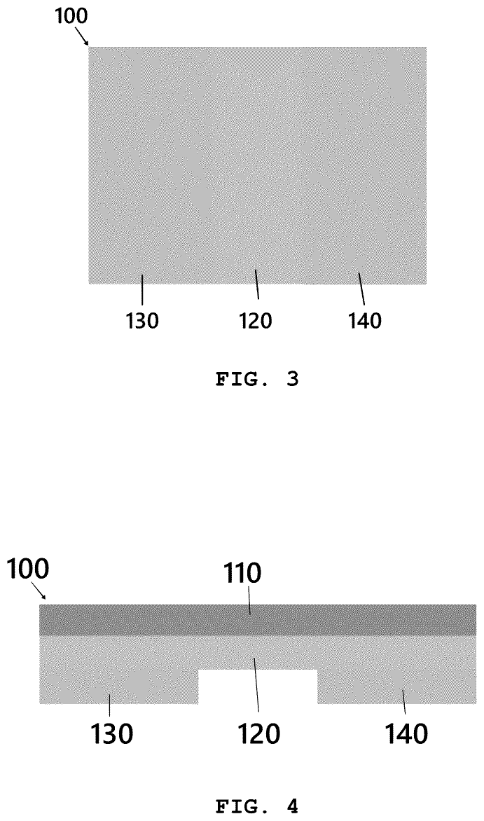

FIG. 1 is a drawing illustrating the overall shape of a three-layer vertical shunt resistor according to a preferred embodiment of the present invention, FIG. 2 is a plan view of a three-layer vertical shunt resistor according to a preferred embodiment of the present invention, FIG. 3 is a bottom view of a three-layer vertical shunt resistor according to a preferred embodiment of the present invention, and FIG. 4 is a cross-sectional view of a three-layer vertical shunt resistor according to a preferred embodiment of the present invention.

Referring to FIGS. 1 to 4. A three-layer vertical shunt resistor (100) according to the present invention may include a first resistor body (120), a second resistor body (110), a first terminal (130), and a second terminal (140). The second resistor body (110) may be diffusion-bonded by a current applied to an upper surface of the first resistor body (120), and the first terminal (130) and the second terminal (140) may be diffusion-bonded by a current applied to a lower surface of the first resistor body (120).

The second resistor body (110) is coupled to the upper portion of the first resistor body (120) and may be formed of a resistive material having better electrical conductivity than the resistive material of the first resistor body (120). The second resistor body (110) may be formed of a single material. The resistive material of the second resistor body (110) may be copper (Cu), nickel (Ni), or chromium (Cr). The thickness of the second resistor body (110) may be smaller than the horizontal and vertical lengths of the first resistor body (120). The thickness of the second resistor body (110) may be 0.02 mm to 0.7 mm.

The first resistor body (120) may include a resistive material. The first resistor body (120) may be formed of an alloy material. The resistive material of the first resistor body (120) may include at least one of a Cu—Mn alloy, a Cu—Mn—Ni alloy, a Cu—Ni alloy, a Ni—Cr alloy, and a Fe—Cr alloy. The thickness of the first resistor body (120) may be 0.15 mm to 1.0 mm.

The first terminal (130) is coupled to the lower portion of the first resistor body (120) and may be formed of a metal material having better electrical conductivity than the resistive material of the first resistor body (120). The metal material may be copper. The thickness of the first terminal (130) may be smaller than the horizontal and vertical lengths of the first resistor body (120). The first terminal (130) may be an electrode or terminal of the three-layer vertical shunt resistor (100). The thickness of the first terminal (130) may be 0.1 mm to 0.8 mm.

The second terminal (140) is coupled to the lower portion of the first resistor body (120), is arranged to be spaced apart from the first terminal (130), and may be formed of a metal material having better electrical conductivity than the resistive material of the first resistor body (120). The metal material may be copper. The thickness of the second terminal (140) may be smaller than the horizontal and vertical lengths of the first resistor body (120). The second terminal (140) may be an electrode or terminal of the three-layer vertical shunt resistor (100). The thickness of the second terminal (140) may be 0.1 mm to 0.8 mm.

The cross-sectional area of the second terminal (140) and the cross-sectional area of the first terminal (130) may be the same or different. The thickness of the cross-sectional area of the second terminal (140) and the cross-sectional area of the first terminal (130) may be the same or different.

The area of the contact surface between the first resistor body (120) and the second resistor body (110) may be larger than the area of the front and side surfaces of the first resistor body (120), respectively. The horizontal and vertical lengths of the first resistor body (120) may each be longer than the thickness of the first resistor body (120). The horizontal and vertical lengths of the contact surface between the first resistor body (120) and the second resistor body (110) may each be longer than the thickness of the first resistor body (120).

The thickness of the three-layer vertical shunt resistor (100) may be smaller than the horizontal and vertical lengths of the first resistor body (120).

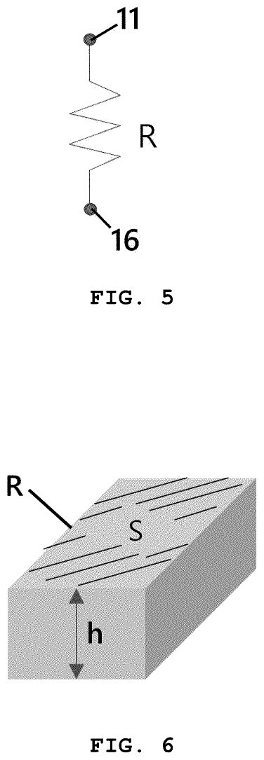

FIG. 5 is a drawing illustrating a shunt circuit of the three-layer vertical shunt resistor of FIG. 1.

Referring to FIG. 5, the first terminal (130) may form a first electrode (11) of the three-layer vertical shunt resistor (100), the second terminal (140) may form a second electrode (16) of the vertical shunt resistor (100), and the resistance values of the first resistor body (120) and the second resistor body (110) may become the resistance value (R) of the three-layer vertical shunt resistor (100). In addition, the first terminal (130) and the second terminal (140) may be used as terminals of the three-layer vertical shunt resistor (100).

FIG. 6 is a drawing for explaining the resistance value of a three-layer vertical shunt resistor according to a preferred embodiment of the present invention.

Referring to FIG. 6, the resistance value (R) of the shunt resistor may be calculated using the following mathematical formula 1.

R=ρ(h/S) [Mathematical formula 1]

Herein, h corresponds to the thickness of the first resistor body (120) and the second resistor body (110) in the present invention, S is the area of the three-layer vertical shunt resistor (100), and in the present invention, it may mean the area of the first resistor body (120) and the product of the horizontal and vertical lengths of the first resistor body (120), and p is a constant value for obtaining R. h corresponds to the sum of the heights of the first resistor body (120) and the second resistor body (110), and the sum of the h value and the height of the first terminal (130) (or the second terminal (140)) may be the height of the three-layer vertical shunt resistor (100), and the height of the three-layer vertical shunt resistor (100) may be the length (L) of the three-layer vertical shunt resistor (100).

In order to implement the three-layer vertical shunt resistor (100) having a resistance value of 1 mΩ, the area (S) of the first resistor body (120) is 0.1936 mm2 and the thickness (L) of the first resistor body (120) is required to be 0.4 mm. Accordingly, the width, height, and thickness of the first resistor body (120) can be implemented as 0.44 mm and 0.44 m, respectively.

In order to implement the three-layer vertical shunt resistor (100) having a resistance value of 4 mΩ, the thickness (L) of the first resistor body (120) in the three-layer vertical shunt resistor (100) having a resistance value of 1 mΩ can be maintained at 0.4 mm, and the width and height of the first resistor body (120) can be reduced by half. That is, the three-layer vertical shunt resistor (100) according to the present invention can increase the resistance value without increasing the length (L), so that a shunt resistor having a large resistance value can be manufactured into a small size, thereby improving the integration of the power module.

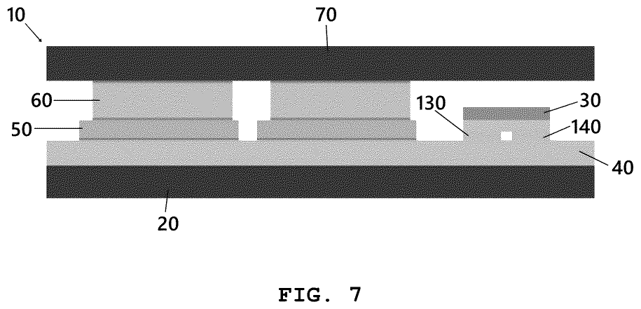

FIG. 7 is a drawing illustrating a semiconductor package according to a preferred embodiment of the present invention.

Referring to FIG. 7, the semiconductor package (10) according to the present invention may include a lower plate (20), a three-layer vertical shunt resistor (30), a circuit board (40), a semiconductor chip (50), a spacer (60), and an upper plate (70). The semiconductor package (10) according to the present invention may include a power semiconductor.

The circuit board (40) may be coupled to the upper portion of the lower plate (20). A circuit may be formed on the circuit board (40), and the circuit board (40) may be a printed circuit board (PCB) or a DBC board.

The upper surface of the three-layer vertical shunt resistor (30) may be spaced apart from the upper plate (70), and the lower surface may be coupled to the circuit board (40). That is, a space may be formed between the three-layer vertical shunt resistor (30) and the upper plate (70). Accordingly, the semiconductor package (10) according to the present invention can be manufactured with a smaller height and width, thereby improving the degree of integration.

The electrode of the three-layer vertical shunt resistor (30) can be connected to the circuit of the circuit board (40) so as to be grounded and energized. Here, the three-layer vertical shunt resistor (30) may include the three-layer vertical shunt resistor (100) according to the present invention described above. The first terminal (130) and the second terminal (140) of the three-layer vertical shunt resistor (30) can each be connected to the circuit of the circuit board (40).

The semiconductor chip (50) may include a high-frequency semiconductor device or a high-output semiconductor device. In addition, the semiconductor chip (50) may be a power device, and for example, can be a SiC Power MOSFET. The semiconductor chip (50) may be mounted on the circuit board (40).

The spacer (60) is connected to the semiconductor chip (50) at the bottom and connected to the upper plate (70) at the top, so that it can dissipate heat from the semiconductor chip (50). The spacer (60) can be connected to each of the semiconductor chip (50) and the upper plate (70) as shoulders.

The semiconductor package (10) according to the present invention can be manufactured in an ultra-small size by using the three-layer vertical shunt resistor (30) according to the present invention, and since the first terminal (130) and the second terminal (140) are arranged in the same layer and direction, it can be manufactured in an even more ultra-small size.

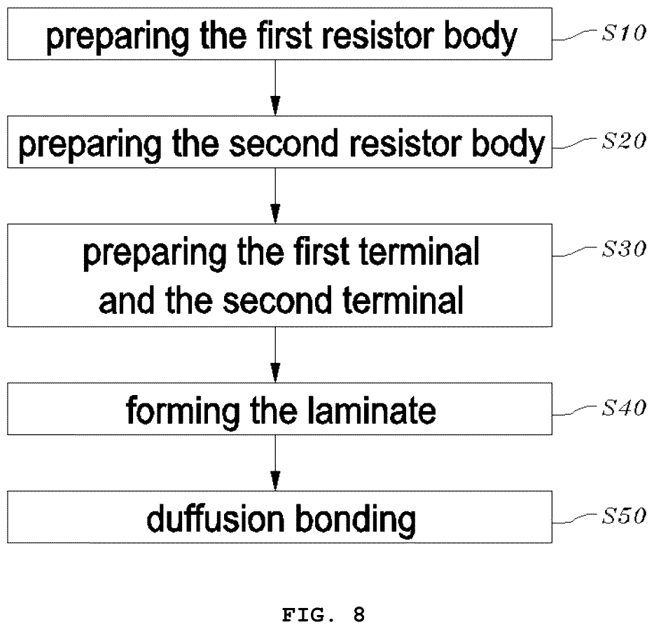

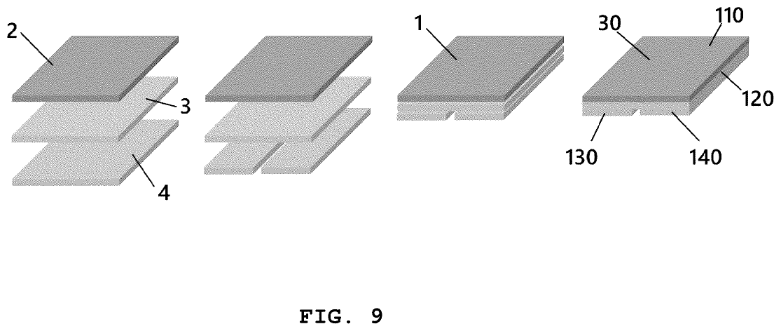

FIG. 8 is a flowchart illustrating the process of performing a preferred embodiment of a method for manufacturing a three-layer vertical shunt resistor according to the present invention and FIG. 9 is a process diagram illustrating the process of performing a preferred embodiment of a method for manufacturing a three-layer vertical shunt resistor according to the present invention.

Referring to FIGS. 8 and 9, the first resistor body (120) including a resistive material (3) is prepared (S10). The resistive material (3) may include at least one of a Cu—Mn alloy, a Cu—Mn—Ni alloy, a Cu—Ni alloy, a Ni—Cr alloy, and an Fe—Cr alloy.

The second resistor body (110) formed of a resistive material (2) having better electrical conductivity than the resistive material (3) of the first resistor body (120) is prepared (S20). The resistive material (2) may be copper (Cu), nickel (Ni), or chromium (Cr). The surface area of the second resistor body (110) may correspond to the surface area of the first resistor body (120).

The first terminal (130) and The second terminal (140) formed of a metal material (4) having better electrical conductivity than the resistive material (3) of the first resistor body (120) are prepared (S30). The metal material (4) may be copper. Herein the sum of the surface areas of the first terminal (130) and the second terminal (140) may be smaller than the sum of the surface areas of the first resistor body (120).

The first terminal (130) and the second terminal (140) are arranged below the first resistor body (120), and the second resistor body (110) is laminated on top of the first resistor body (120) to form a laminate (1) (S40). Here, the first terminal (130) and the second terminal (140) may be arranged to be spaced apart from each other. In the process S40, the first resistor body (120) may be arranged between the first terminal (130) and the second resistor body (110), and the first resistor body (120) may be laminated between the second terminal (140) and the second resistor body (110).

By applying current to the laminate (1), the first terminal (130), the second terminal (140), the first resistor body (120), and the second resistor body (110) are diffusion-bonded to generate the three-layer vertical shunt resistor (30) (S50). The diffusion-bonding process (S50) may include a process of applying pressure and temperature at which a reaction occurs between the first terminal (130) and the first resistor body (120), a process of applying pressure and temperature at which a reaction occurs between the second terminal (140) and the first resistor body (120), and a process of applying pressure and temperature at which a reaction occurs between the second resistor body (110) and the first resistor body (120). The diffusion-bonding process (S50) may be performed at a temperature range of 550° C. or less and a pressure range of 1 MPa or more. The diffusion-bonding process S50 may be performed by a diffusion bonding method. In some embodiments, sintering can be performed using spark plasma sintering (SPS) in process S50.

Diffusion bonding method is a method of bonding base materials by attaching the base materials, pressing the base materials at a temperature below the melting point of the base materials to a degree that plastic deformation is minimized, and so utilizing the diffusion of atoms that occurs between the bonding surfaces of the base materials. Compared to other bonding processes such as the hot press process, the second resistor body (110), the first resistor body (120), the first terminal (130), and the second terminal (140) can be bonded at a lower temperature, thereby minimizing deformation of the three-layer vertical shunt resistor (100) due to heating and reducing process costs.

In addition, since simple pressurization and heating are used in the diffusion bonding method, it is easy to control the amount of diffusion, which is advantageous for bonding dissimilar metals. However, in the actual formation of the bonding layer, if the bonding layer is heated to a high temperature to completely bond the bonding layer, the intermetallic compound layer may grow due to excessive diffusion, which may significantly deteriorate the mechanical performance. In the present invention, since the first resistor body (120) is formed of a resistive material, the melting point of the resistive material is generally lower than the melting point of 1083° C. of copper forming the second resistor body (110), the first terminal (130), and the second terminal (140), so that diffusion bonding can be performed at a low temperature. Preferably, in process S50, diffusion bonding can be performed at a temperature range of 550° C. or less and a pressure range of 1 MPa or more.

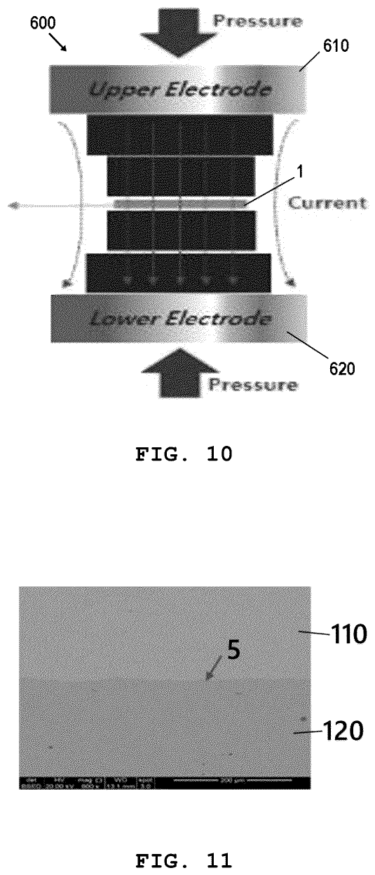

FIG. 10 is a diagram illustrating a diffusion bonding process.

Referring to FIG. 10, in process S50, the laminate (1) can be diffusion bonded with a press device (600). That is, the laminate (1) is placed between the upper press (610) and the lower press (620) of the press device (600), current is allowed to flow from the upper press (610) to the lower press (620), and the upper press (610) and the lower press (620) are brought into close contact to bond the second resistor body (110), the first resistor body (120), the first terminal (130), and the second terminal (140) of the laminate (1). The laminate (1) that has passed through the press device (600) can have a shape as illustrated in FIG. 1.

FIG. 11 is a diagram illustrating a photograph of a bonding portion of a three-layer vertical shunt resistor according to a preferred embodiment of the present invention.

Referring to FIG. 11, the three-layer vertical shunt resistor (100) according to the present invention is diffusion bonded by the applied current, so that there are no defects, unevenness, or voids at the bonding portion (5).

It will be apparent to those skilled in the art that the present invention can be embodied in other specific forms without departing from the spirit and essential characteristics of the invention. Thus, the above embodiments are to be considered in all respects as illustrative and not restrictive. The scope of the invention should be determined by reasonable interpretation of the appended claims and all change which comes within the equivalent scope of the invention are included in the scope of the invention.

What is claimed is:

1. A three-layer vertical shunt resistor comprising:
a first resistor body including a resistive material;
a second resistor body coupled to an upper portion of the first resistor body and formed of a resistive material having better electrical conductivity than the resistive material of the first resistor body;
a first terminal coupled to a lower portion of the first resistor body and formed of a metal material having better electrical conductivity than the resistive material the first resistor body; and
a second terminal coupled to a lower portion of the first resistor body and arranged to be spaced apart from the first terminal and formed of a metal material having better electrical conductivity than the resistive material the first resistor body.

2. The three-layer vertical shunt resistor of claim 1, wherein the resistive material of the first resistor body includes at least one of a Cu—Mn alloy, a Cu—Ni alloy, a Ni—Cr alloy, a Cu—Mn—Ni alloy, and an Fe—Cr alloy.

3. The three-layer vertical shunt resistor of claim 1, wherein the thickness of the first resistor body is 0.15 mm to 1.0 mm.

4. The three-layer vertical shunt resistor of claim 1, wherein the thickness of the second resistor is 0.02 mm to 0.7 mm.

5. The three-layer vertical shunt resistor of claim 1, wherein the thickness of the first terminal or the thickness of the second terminal is 0.1 mm to 0.8 mm.

6. The three-layer vertical shunt resistor of claim 1, the metal material of the second resistor body is formed of a single material.

7. A power semiconductor comprising:
the three-layer vertical shunt resistor according to claim 1.

8. A method for manufacturing a three-layer vertical shunt resistor comprising:
a step of preparing a first resistor body including a resistive material;
a step of preparing a second resistor body formed of a resistive material having better electrical conductivity than the resistive material of the first resistor body;
a step of preparing a first terminal and a second terminal formed of a metal material having better electrical conductivity than the resistive material of the first resistor body;
a step of forming a laminate by laminating the first resistor body between the second resistor body and the first terminal, the first resistor body between the second resistor body and the second terminal, and the first terminal and the second terminal in a spaced apart form; and
a step of applying a current to the laminate to diffusion-bond the first terminal, the second terminal, the first resistor body, and the second resistor body.

9. A power semiconductor comprising:
the three-layer vertical shunt resistor according to claim 2.

10. A power semiconductor comprising:
the three-layer vertical shunt resistor according to claim 3.

11. A power semiconductor comprising:
the three-layer vertical shunt resistor according to claim 4.

12. A power semiconductor comprising:
the three-layer vertical shunt resistor according to claim 5.

13. A power semiconductor comprising:
the three-layer vertical shunt resistor according to claim 6.
